(19) United States
(12) Patent Application Publication
(10) Pub. No.: US 2005/0217714 A1
(43) Pub. Date: Oct. 6, 2005

(54) Exhaust heat recovery system

(75) Inventors: Yoshiaki Nishijima, Toyokawa-city (JP); Katsuhide Akimoto, Nishio-city (JP); Yurio Nomura, Nagoya-city (JP); Tatsuyoshi Sasaki, Kyoto-shi (JP); Keiji Tsukamoto, Kyoto-shi (JP); Tsutomu Sakai, Kyoto-shi (JP)

Correspondence Address: NIXON & VANDERHYE, PC, 901 NORTH GLEBE ROAD, 11TH FLOOR, ARLINGTON, VA, 22203, US

(73) Assignee: DENSO CORPORATION, Kariya-city (JP)

(21) Appl. No.: 11/095,608

(22) Filed: Apr. 1, 2005

(30) Foreign Application Priority Data
Apr. 2, 2004 (JP) 2004-110128

(51) Int. Cl. F25B 21/02; H01L 35/28

(52) U.S. Cl. 136/204; 136/208

(57) ABSTRACT

A thermoelectric module 2 constituting an exhaust heat recovery system has p-type semiconductors 3p and n-type semiconductors 3n which both constitute thermoelements 3 for converting a difference in temperature between high temperature side end portions 21 and low temperature side end portions 22 into electricity. The thermoelectric module 2 is constructed such that the n-type semiconductors 3n and the p-type semiconductors 3p are stacked alternately along a longitudinal direction of an exhaust pipe portion 20 with heat insulating support portions 41, 42 being interposed therebetween, and the n-type semiconductors 3n and the p-type semiconductors 3p are electrically connected to each other via electrode members at the high temperature side end portions 21 and the low temperature side end portions 22.

### BACKGROUND OF THE INVENTION

1. Field of the Invention

The present invention relates to an exhaust heat recovery system that is disposed in an exhaust path, of an internal combustion engine in an automobile, to recover the exhaust heat carried by exhaust gases.

2. Description of the Related Art

The energy efficiency of an automobile equipped with, for example, a gasoline engine is low and on the order of 15 to 20%. One of main factors which reduce the energy efficiency ratio is that a large quantity of thermal energy is carried away together with exhaust gases. To cope with this, conventionally, techniques have been proposed to enhance the total energy efficiency ratio by aggressively using the exhaust heat carried by the exhaust gases (for example, refer to Japanese Unexamined Patent Publication No. 2000-286469).

In the conventional technique, there is disclosed an exhaust heat recovery system in which thermoelements which can convert a difference in temperature into electricity (or generate electricity) are disposed in an exhaust passageway.

However, the energy recovery efficiency ratio of the exhaust heat recovery system according to the conventional technique is not satisfactory, and therefore, the development of new exhaust heat recovery systems which can increase the energy recovery efficiency ratio have been desired.

### SUMMARY OF THE INVENTION

The present invention was made in view of the problem inherent in the conventional techniques and an object thereof is to provide an exhaust heat recovery system which can efficiently recover exhaust heat carried by exhaust gases discharged from an internal combustion engine.

According to the present invention, there is provided an exhaust gas recovery system having an exhaust path which allows the passage of exhaust gases of an internal combustion engine therethrough and a thermoelectric module disposed in the exhaust path, the thermoelectric module having;
an exhaust pipe portion which is a space for allowing the passage of the exhaust gases therethrough,
p-type semiconductors and n-type semiconductors which both constitute thermoelements for converting a difference in temperature between high temperature side end portions and low temperature side end portions into electricity,
low temperature side heat exchanging portions disposed at the low temperature side end portions, and
high temperature side heat exchanging portions disposed at the high temperature side end portions, wherein
in the thermoelectric module, the n-type semiconductors and the p-type semiconductors are stacked alternately along a longitudinal direction of the exhaust pipe portion with heat insulating support members being interposed therebetween and are electrically connected to each other at the high temperature side end portions and the low temperature side end portions via electrode members.

The thermoelectric module of the exhaust heat recovery system according to the present invention is such that the n-type semiconductors and the p-type semiconductors are stacked alternately along the longitudinal direction of the exhaust pipe portion with the heat insulating support members being interposed therebetween. Due to this, in the thermoelectric module, the convection of air between the high temperature side end portions and the low temperature side end portions can be prevented. Consequently, the difference in temperature between the high temperature side end portions and the low temperature side end portions can be maintained high, thereby making it possible to further enhance the exhaust heat recovery efficiency.

Thus, according to the present invention, there can be provided an exhaust heat recovery system which has superior characteristics represented by a high exhaust heat recovery efficiency and by electrical reliability.

The thermoelectric module of the exhaust heat recovery system according to the present invention has, as has been described above, thermoelements for converting the difference in temperature into electricity. A known thermoelement, made up of a combination of a n-type semiconductor and a p-type semiconductor, can be used as the thermoelement.

In addition, it is preferable that the high temperature side heat exchanging portions and the low temperature side heat exchanging portions exhibit fin shapes which have a large surface area. Furthermore, as the heat insulating support members, for example, fibers of silica or alumina, and other types of heat insulating materials, can be used. Moreover, in the exhaust pipe portion, for example, piping which allows the passage of exhaust gases can be disposed close to the high temperature side heat exchanging portions.

Furthermore, the electrode members, which electrically connect the n-type semiconductors with the p-type semiconductors at the high temperature side end portions and the low temperature side end portions, may be disposed on an outer circumferential surface of the thermoelectric module which constitutes a stacked structure or may be stacked between the p-type semiconductors and the n-type semiconductors, respectively, parallel to the heat insulating support members. In particular, in the event that the electrode members are stacked together with the heat insulating support members between the p-type semiconductors and the n-type semiconductors, electric contacts with the electrode members can be provided on the stacking surfaces of the respective semiconductors and, therefore, the electrical reliability can easily be ensured in the thermoelectric module.

In addition, in the thermoelectric module, it is preferable that the thermoelement is made up of a combination of a plurality of separated thermoelements which have different peak temperatures where a maximum thermoelectric efficiency can be obtained and that the respective semiconductors which make up the separated thermoelements having a higher peak temperature are disposed close to the exhaust pipe portion.

In this case, the characteristics of the respective separated thermoelements can be exhibited more efficiently by disposing the respective semiconductors which make up the separated thermoelements having the higher peak temperature, where the maximum thermoelectric efficiency can be obtained, close to the exhaust pipe portion thereby making it possible to enhance the energy recovery efficiency.

Additionally, in the thermoelectric module, it is preferable that two or more combinations of the n-type semiconductor and the p-type semiconductor are stacked together along the longitudinal direction of the exhaust pipe portion and that the arrangement of the respective thermoelements is modified such that a ratio (A/B) of a thickness A in a radial direction of the respective semiconductors, which make up a high temperature element which is the separated thermoelement having a highest peak temperature, and a thickness B in a radial direction of the respective semiconductors, which make up a low temperature element having a lowest peak temperature, becomes larger towards an upstream side of the exhaust pipe portion.

In this case, the thermoelectric module is such that the radial thickness ratio (A/B) of the respective separated thermoelements is modified according to a temperature distribution thereof in which the exhaust gas temperature becomes higher towards an upstream side of a flow of exhaust gases. Therefore, the respective separated thermoelements which make up the thermoelectric module can be used in proper temperature regions where high efficiency can be obtained, thereby making it possible to enhance the exhaust heat recovery efficiency further.

In addition, it is preferable that the n-type semiconductor, the p-type semiconductor and the heat insulating support member are each formed into an annular shape having a through hole provided in an inner circumferential portion thereof and that the exhaust pipe portion is formed on an inner circumferential side of the n-type semiconductor, the p-type semiconductor and the heat insulating support member which are stacked together in such a manner that the respective through holes communicate with one another.

In this case, a construction can be realized in which exhaust heat carried by exhaust gases flowing through the exhaust pipe portion can be transmitted directly to the thermoelement and, therefore, the exhaust heat recovery system can be such as to have a higher energy recovery efficiency.

Additionally, it is preferable that the electrode member is a conductive layer which is disposed on part of an external surface of the heat insulating support member.

In this case, the p-type semiconductor and the n-type semiconductor, which are stacked so as to face each other via the electrode members which are made up of the conductive layers disposed on the external surfaces of the heat insulating support member, can be electrically connected to each other in a highly secure fashion.

In addition, it is preferable that the electrode member is made up of the high temperature side heat exchanging portion and the low temperature side heat exchanging portion.

In this case, an efficient heat exchanging can be implemented via the respective heat exchanging portions which constitute the electrode member for connecting electrically the n-type semiconductor with the p-type semiconductor, thereby making it possible to increase the exhaust heat recovery efficiency further.

Additionally, it is preferable that the high temperature side heat exchanging portion protrudes into the interior of the exhaust pipe portion.

In this case, the heat exchange between the exhaust gases and the high temperature side heat exchanging portion is promoted, thereby making it possible to increase the exhaust heat recovery efficiency of the exhaust heat recovery system.

The present invention may be more fully understood from the description of preferred embodiments of the invention, as set forth below, together with the accompanying drawings.

### BRIEF DESCRIPTION OF THE DRAWINGS

In the drawings:

FIG. 1 is an explanatory view showing an exhaust heat recovery system (a portion indicated by A) according to a first embodiment of the invention which is incorporated in an exhaust path of an internal combustion engine;

FIG. 2 is an explanatory view showing the exhaust heat recovery system according to the first embodiment;

FIG. 3 is a partially sectional view showing a thermoelectric module (a portion indicated by B in FIG. 2) according to the first embodiment;

FIG. 4 is an enlarged sectional view showing a sectional construction of the thermoelectric module according to the first embodiment which is taken along a longitudinal direction thereof;

FIG. 5 is an explanatory view showing a stacked construction of the thermoelectric module according to the first embodiment;

FIG. 6 is a sectional view showing stacked components which make up the thermoelectric module according to the first embodiment;

FIG. 7 is a sectional view showing stacked components which make up the thermoelectric module according to the first embodiment;

FIG. 8 is an enlarged sectional view showing a sectional construction of another thermoelectric module according to the first embodiment;

FIG. 9 is a sectional view showing a sectional shape of a further thermoelectric module according to the first embodiment;

FIG. 10 is a sectional view showing a sectional construction of a thermoelectric module according to the first embodiment;

FIG. 11 is a sectional view showing another thermoelectric module according to the first embodiment;

FIG. 12 is a sectional view showing respective semiconductors according to a second embodiment of the invention (in FIG. 12A, a semiconductor constituting a low temperature element is shown, and in FIG. 12B, a semiconductor making up a high temperature element is shown);

FIG. 13 is a sectional view showing a component comprising a combination of the semiconductor making up the low temperature element and the semiconductor making up the high temperature element according to the second embodiment;

FIG. 14 is a partially sectional view showing a thermoelectric module according to a third embodiment of the invention in which the thickness ratio (A/B) of separated thermoelements is modified along a longitudinal direction thereof; and

FIG. 15 is an enlarged sectional view showing a sectional construction of the thermoelectric module according to the third embodiment.

### DESCRIPTION OF THE PREFERRED EMBODIMENTS

### First Embodiment

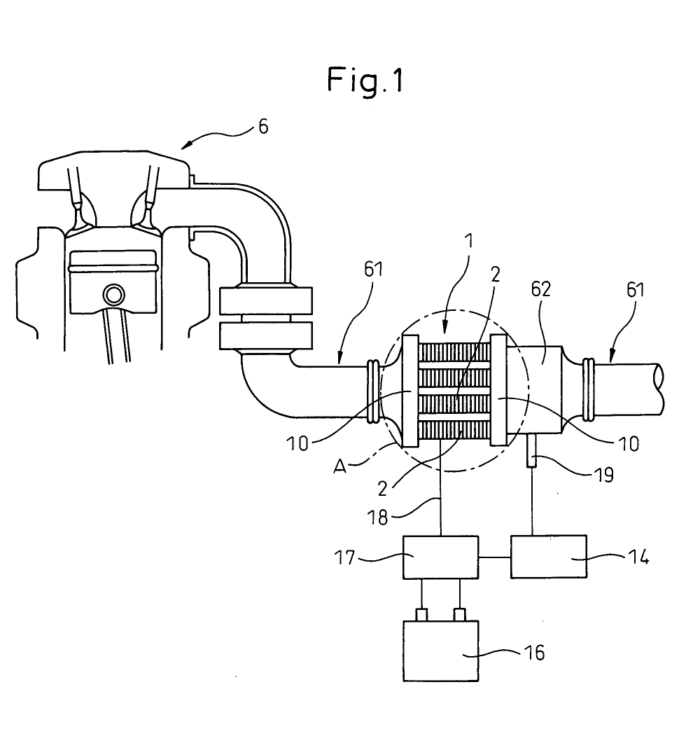

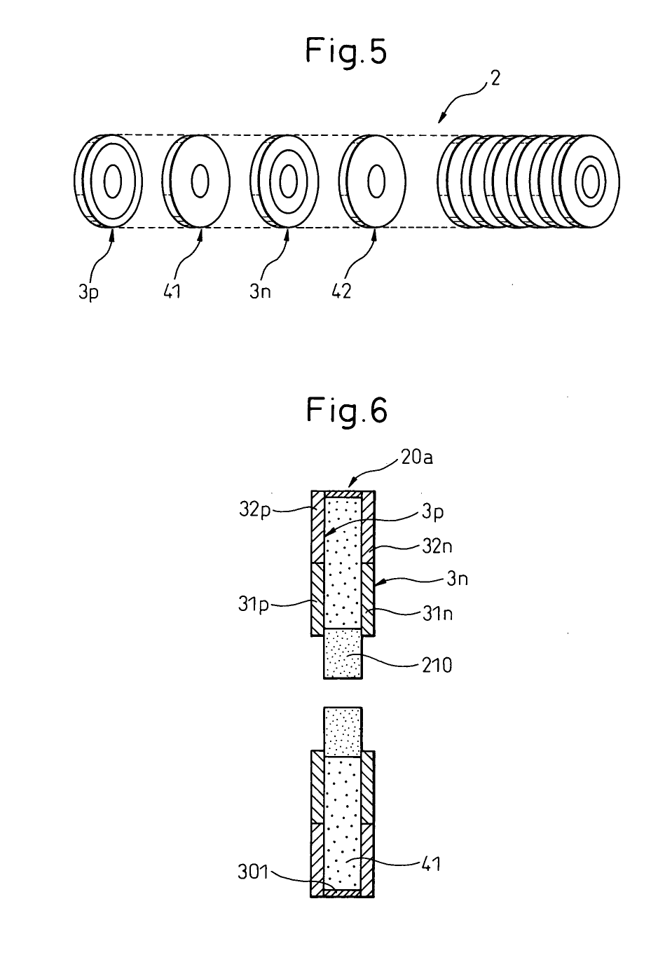

An exhaust heat recovery system according to a first embodiment of the invention will be described with reference to FIGS. 1 to 11.

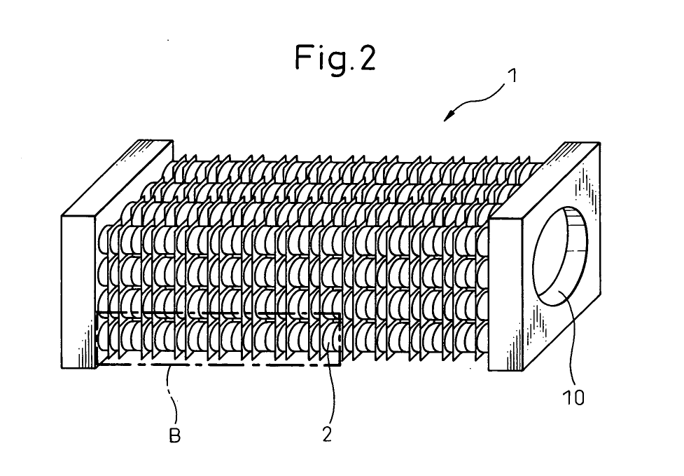

As shown in FIGS. 1 and 2, the exhaust heat recovery system according to the embodiment has an exhaust path 10 which allows the passage of exhaust gases of an internal combustion engine 6 and thermoelectric modules 2 which are disposed in the exhaust path 10.

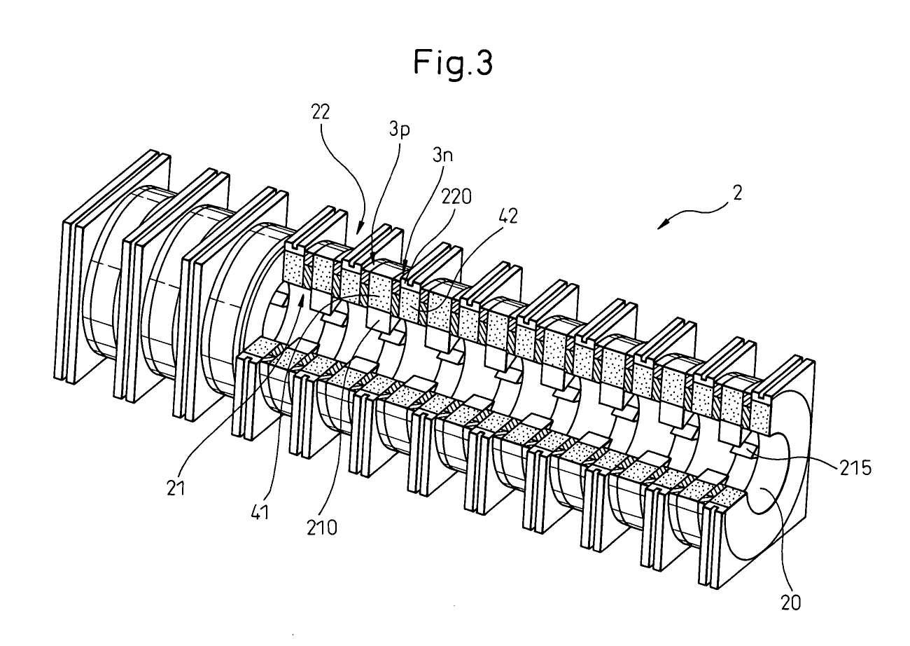

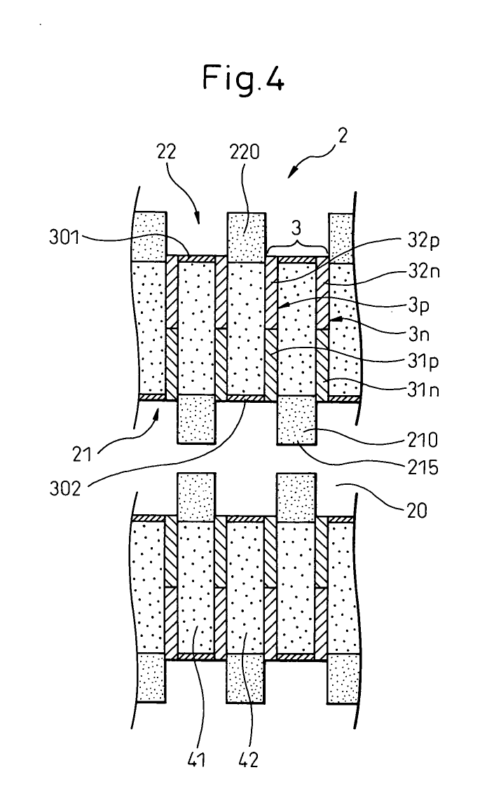

The thermoelectric module 2, as shown in FIGS. 3 and 4, has an exhaust pipe portion 20 which allows the passage of exhaust gases therethrough, p-type semiconductors 3p and n-type semiconductors 3n which both constitute thermoelements 3 which each convert a difference in temperature between a high temperature end portion 21 and a low temperature end portion 22 into electricity, low temperature side heat exchanging portions 220 disposed at the low temperature side end portions 22 of the thermoelectric module 2, and high temperature side heat exchanging portions 210 disposed at the high temperature side end portions 21 of the thermoelectric module 2.

In the thermoelectric module 2, the n-type semiconductors 3n and the p-type semiconductors 3p are stacked alternately along a longitudinal direction of the exhaust pipe portion 20 with heat insulating members 4 being interposed therebetween. In addition, the n-type semiconductors 3n and the p-type semiconductors 3p are electrically connected to each other via electrode members 301, 302 at the high temperature side portions 21 and the low temperature side end portions 22.

The details of the construction of the thermoelectric module 2 will be described below.

As shown in FIGS. 1 and 2, the exhaust heat recovery system 1 according to the embodiment is a system incorporated in an exhaust path 61 of the engine 6 of an automobile and includes, as has been described above, the exhaust path 10 which is connected to the exhaust path 61 and the thermoelectric module 2. Note that, in the exhaust heat recovery system 1 according to the embodiment, part of the exhaust path 10 is made up of the exhaust pipe portions 20 of the thermoelectric modules 2.

As shown in FIGS. 3 to 5, the thermoelectric module 2 exhibits a stacked construction which results from alternate stacking of the n-type semiconductors 3n which are each formed into substantially an annular flat plate-like shape, the p-type semiconductors 3p which are each formed into substantially an annular flat plate-like shape and the heat insulating support members 4 which are each formed into substantially an annular flat plate-like shape. Then, the exhaust pipe portion 20 is formed on an inner circumferential side of the thermoelectric element 2 to allow the passage of exhaust gases therethrough.

In the thermoelectric module 2, a minimum unit of a thermoelement 3 is formed by virtue of a combination of the heat insulating support member 4 and the electrode member 301, 302 (in this embodiment, the electrode members are formed by virtue of a sputtering process, and hence the members are also described as sputtered layers 301, 302, as required) and the n-type semiconductor 3n and the p-type semiconductor 3p which are stacked on sides of the heat insulating support members 4, respectively. Then, in the thermoelectric module 2 according to the embodiment, a plurality of minimum units resulting from the aforesaid combination are stacked along the longitudinal direction of the exhaust pipe portion 20.

The heat insulating support member 4 is such that fibers made from silica/alumina having excellent electric insulating properties are formed into substantially the annular flat plate-like shape. As this heat insulating support member 4, there are a primary heat insulating support member 41 in which the high temperature side heat exchanging portion 210 made of copper or SVS as a material is fitted on an inner circumferential side thereof and a secondary heat insulating support member 42 on which the low temperature side heat exchanging portion made of copper or SVS as a material is fitted on an outer circumferential side thereof. Then, in this embodiment, as the electrode members 301, 302 for electrically connecting the n-type semiconductor 3n with the p-type semiconductor 3p, sputtered layers (hereinafter, described as sputtered layers 301, 302, as required) are formed on part of external surfaces of the heat insulating support members 41, 42.

In the primary heat insulating support member 41, the sputtered layer 301 is formed along outer circumferential edge portions on both sides and an outer circumferential surface thereof by sputtering platinum, which is a conductive material, onto the respective portions and the surface. In addition, in the secondary heat insulating support member 42, the sputtered layer 302 is formed along inner circumferential edge portions on both sides and on an inner circumferential surface thereof by sputtering platinum, which is a conductive material, to the respective portions and the surface. Here, the sputtered layers 301, 302 which are formed on the outer and inner circumferential surfaces and part of the sides of the respective heat insulating support members 4 function, as has been described above, as the electrode members which electrically connect the n-type semiconductors 3n with the p-type semiconductors 3p.

The high temperature side heat-exchanging portion 210 is a member which exhibits a ring-like shape. Then, an outer circumferential shape thereof substantially coincides with an inner circumferential shape of the primary heat insulating support member 41, so that the high temperature side heat exchanging portion 210 can fit in the primary heat insulating support member 41 on the inner circumferential side of the latter. In addition, an inner circumferential shape of the high temperature side heat exchanging portion 210 exhibits a shape in which a plurality of ribs 215, which protrude towards a center and which is each formed into a shape of a ridge which extends in the longitudinal direction of the exhaust pipe portion 20, are formed in a circumferential direction. The ribs 215 are such as to function as heat absorbing fins, helping improve the heat exchanging efficiency.

Note that a catalyst (not shown) composed of platinum, palladium and rhodium can be carried on the surfaces of the respective ribs 215 on the high temperature side heat exchanging portion 210. As this occurs, heat of higher temperatures can be taken in as a result of heat release occurring when exhaust gases react with the catalyst for activation.

In addition, the low temperature side heat exchanging portion 220 is a member which exhibits a square-like shape in which a substantially circular hole, which substantially coincides with the external shape of the secondary heat insulating support member 42, is formed on an inner circumferential side thereof, so that the low temperature side heat exchanging portion 220 fits on an outer circumferential side of the primary heat insulating support member 42.

Note that, in this embodiment, in order to avoid the occurrence of electrical short circuit between the n-type semiconductor 3n and the p-type semiconductor 3p which are stacked adjacent to each other via the respective heat exchanging portions 210, 220, of the external surfaces of the respective heat exchanging portions 210, 220, an alumina flame-sprayed layer (not shown) is formed on at least the sides (stacking surfaces) thereof in an attempt to ensure the required electrical insulation, as well as maintaining the thermoelectric conductivity.

As shown in FIGS. 3 to 5, the thermoelectric module 2 is such that as many as 46 sets of the secondary heat insulating support members 42 having the low temperature side heat exchanging portions 220 which are fitted on the outer circumferences thereof, the p-type semiconductors 3p, the primary heat insulating support members 41 having the high temperature side heat exchanging portions 210 which are fitted in the inner circumferences thereof and the n-type semiconductors 3n are stacked together while maintaining that stacking order.

In this thermoelectric module 2, the respective semiconductors 3p, 3n are brought into abutment with the sputtered layer 302 formed along the inner circumferential edge portions and the inner circumferential surface of the adjacent secondary heat insulating support member 42 at the high temperature side end portions 21 thereof and with the sputtered layer 301 formed along the outer circumferential edge portions and the outer circumferential surface of the adjacent primary heat insulating support member 41 which resides on an opposite side to the secondary heat insulating support member 42 in the stacking direction at the low temperature side end portions thereof. On the other hand, the electrical insulating properties are ensured on the portions of the stacking surfaces of the respective heat insulating support members 4 where no sputtered layers 301, 302 are formed, as well as the both sides thereof which correspond to the stacking surfaces of the respective heat exchanging portions 210, 220 on which the alumina flame-sprayed layers are formed.

Consequently, in the thermoelectric module 2, a one-way electric path is formed which is routed to pass through the interior of the p-type semiconductor 3p by way of the electric contact between the sputtered layer 302 of the secondary heat insulating support member 42 and the high temperature side end portion 21 of the p-type semiconductor 3p, then passing through the interior of the n-type semiconductor 3n by way of the electric contact between the low temperature side end portion 22 of the p-type semiconductor 3p and the sputter layer 301 of the primary heat insulating support member 41, and reaching to the high temperature side end portion 21 of the next p-type semiconductor 3p by way of the electric contact between the high temperature side end portion 21 of the n-type semiconductor 3n and the sputtered layer 302 of the secondary heat insulating support member 42.

Furthermore, as shown in FIG. 4, the thermoelement 3 according to the embodiment is made up of two separated thermoelements having different peak temperatures at which a maximum thermoelectric efficiency can be obtained. To be specific, a combination of a p-type semiconductor 31p and an n-type semiconductor 31n which both constitute a thermoelement having a high peak temperature is disposed radially inwardly of the thermoelectric module 2 or is disposed so as to be closer to the exhaust pipe portion 20 side, whereas a combination of a p-type semiconductor 32p and an n-type semiconductor 32n which both constitute a thermoelement having a low peak temperature is disposed radially outwardly of the thermoelectric module 2 or is disposed so as to be apart from the exhaust pipe portion 20.

Note that in this embodiment, CoSb and ZnSb are used, respectively, for the n-type semiconductor 31n and the p-type semiconductor 31p which constitute the high temperature thermoelement, whereas Bi₂Te₃ is used both for the n-type semiconductor 32n and the p-type semiconductor 32p which constitute the low temperature thermoelement.

Here, the construction of the thermoelectric module 2 will be described in greater detail, and a fabrication process thereof will be described briefly.

Firstly, a substantially annular flat plate-like component was prepared in which a primary heat insulating support member 41 having a sputtered layer 301 formed so as to cover an outer circumferential surface and outer circumferential edge portions on both sides thereof is combined with a high temperature side heat exchanging portion 210 having alumina flame-sprayed layers formed on both sides thereof. Then, ZnSb was flame sprayed onto a front side of the substantially annular flat plate-like component which was being rotated like a disk over a range expanding from a predetermined radial position to an inner circumferential side thereof so as to form a p-type semiconductor 31p. Thereafter, Bi₂Te₃ was flame-sprayed onto the front side of the same component over a range expanding from the predetermined position to an outer circumferential edge portion thereof so as to form a p-type semiconductor 32p.

Afterwards, a flame spray treatment was implemented on a rear side of the stacking component 20a. CoSb was flame sprayed onto the rear side of the stacking component 20a which was being rotated in a similar fashion to that described above over a range expanding from a predetermined radial position to an inner circumferential edge portion thereof so as to form an n-type semiconductor 31n. Then, Bi₂Te₃ was flame sprayed onto the rear side of the same component over a range expanding from the predetermined position to an outer circumferential side thereof so as to form an n-type semiconductor 32n.

By implementing the flame spray treatments as described above, a stacking component 20a, as shown in FIG. 6, was obtained in which the respective semiconductors are disposed on the both sides of the primary heat insulating support member 41 in which the high temperature side heat exchanging portion 210 is fitted. On the front side of the stacking component 20a, the p-type semiconductor 31p made from ZnSb is formed on the inner circumferential side thereof, while the p-type semiconductor 32p made from Bi₂Te₃ is formed on the outer circumferential side thereof. Furthermore, on the rear side of the stacking component 20a, the n-type semiconductor 31n made from CoSb is formed on the inner circumferential side thereof, while the n-type semiconductor 32n made from Bi₂Te₃ is formed on the outer circumferential side thereof.

Note that, in the aforesaid flame-spray treatments, the materials may be changed gradually at the boundary portion between the p-type semiconductor 31p (the n-type semiconductor 31n) and the p-type semiconductor 32p (the n-type semiconductor 32n) so as to increase the thickness in the radial direction at the boundary portion, or the thickness in the radial direction at the boundary portion may be decreased so that the materials are changed drastically in the radial direction.

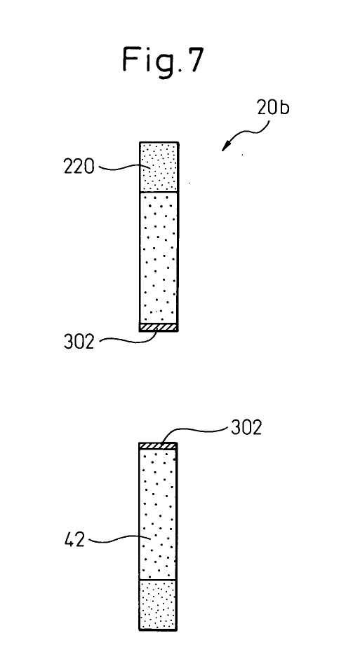

On the other hand, as a stacking component 20b (FIG. 7) that is to be stacked together with the stacking component 20a, a secondary heat insulating support member 42 having a sputtered layer 302 formed so as to cover an inner circumferential surface and inner circumferential edge portions on both sides thereof is combined with a low temperature side heat exchanging portion 220 having alumina flame sprayed layers formed on both sides thereof as insulating layers.

Then, in this embodiment, 46 stacking components 20a and 46 stacking components 20b were stacked alternately so as to obtain a thermoelectric module 2. Note that, in stacking the stacking components 20a and the stacking components 20b, the respective stacking components 20a, 20b were joined to each other using a high temperature silver paste.

The construction and operation of the exhaust heat recovery system 1 will be described below which incorporates therein the thermoelectric modules 2 which are obtained as described above.

As shown in FIG. 1, in the exhaust heat recovery system 1, a pair of lead wires 14 which are electrically connected to the thermoelements 3 of the respective thermoelectric modules 2, is connected to a battery 16 via a conversion circuit 17. In addition, the conversion circuit 17 is electrically connected to an ECU 18 and is constructed so as to execute a power generating mode, for the thermoelectric module 2, at an appropriate timing by switching over circuits based on an instruction from the ECU 18. Note that the power generating mode of the thermoelectric module 2 means a mode for performing an operation to convert a difference in temperature between the high temperature side end portion 21 and the low temperature side end portion 22 of the thermoelement 3 into electricity.

Then, in this embodiment, the power generating mode in which power is generated by the thermoelements 3 is executed by an instruction from the ECU 18 in the event that the temperature of exhaust gases measured by a temperature sensor 19 is a predetermined temperature or higher. Note that the predetermined temperature is such as to correspond to a temperature at which catalyst components of a catalytic converter 62 are put into an activated state.

Namely, the exhaust heat recovery system 1 according to the embodiment does not implement the power generation by the thermoelectric modules 2 in the event that the catalytic converter 62 disposed downstream of the thermoelectric modules 2 is not heated to the temperature at which the activated state is produced. On the other hand, in the event that the catalytic converter 62 disposed downstream of the thermoelectric modules 2 is sufficiently activated, the thermoelements 3 of the thermoelectric modules 2 are made to perform power generating operations, whereby the temperature of exhaust gases can be decreased to some extent so as to suppress an unnecessary increase in temperature of the catalytic converter 62, thereby making it possible to maintain a stable purifying performance.

Thus, with the exhaust heat recovery system 1 according to the embodiment, direct heat exchange can be realized between exhaust gases passing through the exhaust pipe portion 20 formed on the inner circumferential side of the thermoelectric module 2 and the thermoelements 3 which are disposed in such a manner as to surround the outer circumferential side of the exhaust pipe portion 20. Therefore, with the exhaust heat recovery system according to the embodiment, the exhaust heat recovery efficiency can be increased.

Furthermore, the thermoelements 3 of the thermoelectric module 2 are constructed such that the high temperature side separated thermoelements 31p, 31n and the low temperature side separated thermoelements 32p, 32n are stacked in the radial direction on the outer circumferential side of the exhaust pipe portion 20. Namely, in the thermoelectric module 2, a large temperature difference between the high temperature side heat exchanging portion 210 and the low temperature side heat exchanging portion 220 is covered by the two different types, in temperature properties, of separated thermoelements which have the different peak temperatures. Due to this, in the thermoelectric module 2, the respective separated thermoelements which constitute the thermoelements thereof can be used with high efficiency. Therefore, the exhaust heat recover system 1 according to the embodiment can provide superior characteristics including a high recovery efficiency of exhaust heat which is carried by the exhaust gases.

In addition, slits can be provided in the respective semiconductors 3p, 3n which constitute the thermoelements 3, the heat insulating support members 4, the high temperature side heat exchanging portions 210 or the low temperature side heat exchanging portions 220 in such a manner as to be separated in the circumferential direction. In this case, deformation stress generated by virtue of thermal expansion or contraction can be absorbed by the slits so formed to thereby suppress the generation of stress in the interior of each member.

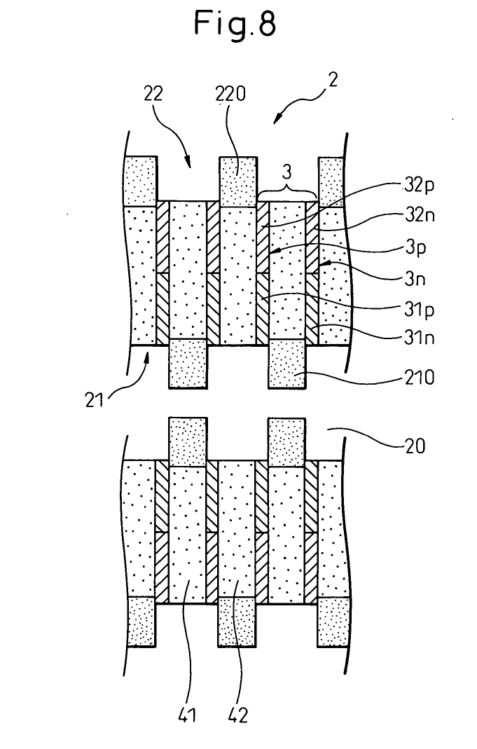

Furthermore, the sputtered layers (denoted by reference numerals 301, 302 in FIG. 4) on the external surfaces of the respective heat insulating support members 41, 42 which constitute the thermoelectric module 2 can be omitted, and instead of the sputtered layers, the high temperature side heat exchanging portions 210 and the low temperature heat exchanging portions 220 can be used as the electrode members, as shown in FIG. 8. In this case, the alumina flame sprayed layers functioning as insulation layers between the respective heat exchanging portions 210, 220 and the respective semiconductors 3n, 3p can be deleted to thereby increase the energy recovery efficiency further. Hence, as the thermoelectric module, the energy recovery efficiency can be increased further.

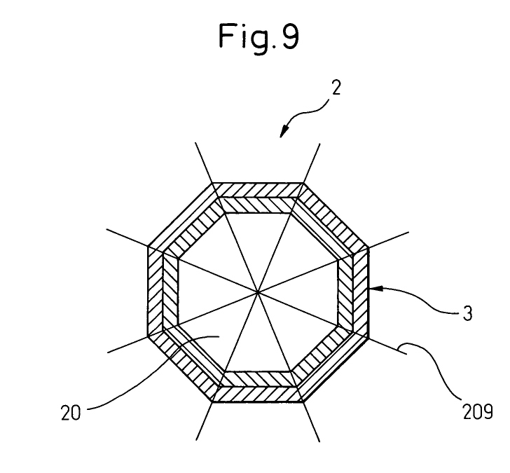

Additionally, the sectional shape of the thermoelectric module is not limited to the circular shape embodied in this embodiment and can be formed into various shapes including a polygonal shape as shown in FIG. 9. In FIG. 9, a thermoelectric module 2 has an octagonal cross section constituted by respective members which are each divided into 8 pieces by seven slits 209 provided circumferentially at equal intervals.

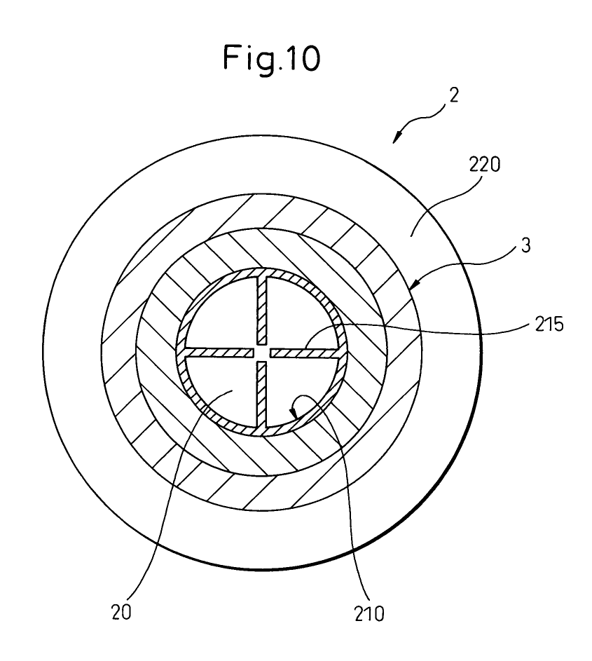

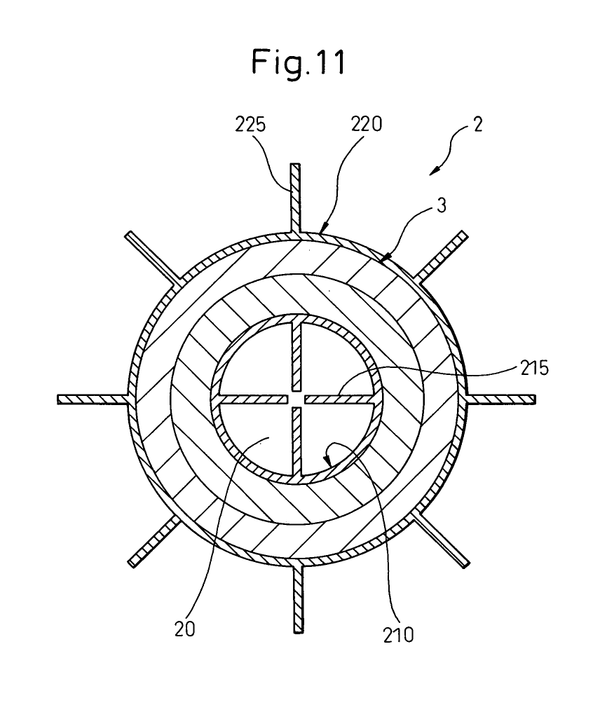

Furthermore, as shown in FIG. 10, a substantially circular flat plate-like high temperature side heat exchanging portion 220 may be formed in place of the substantially square-like high temperature side heat exchanging portion, and the ribs 215 at the low temperature side heat exchanging portion may be replaced by protruding pieces, in this case, four protruding pieces, which protrude towards the center of the exhaust pipe portion 20. Moreover, as shown in FIG. 11, fins 225, which are constituted by protruding pieces which protrude radially outwardly, can be formed in place of the flat plate-like high temperature side heat exchanging portion.

### Second Embodiment

A second embodiment is such that the fabrication process of the thermoelectric module 2 is modified based on the exhaust heat recovery system according to the first embodiment. The contents of the second embodiment will be described using FIGS. 6, 7, 12 and 13.

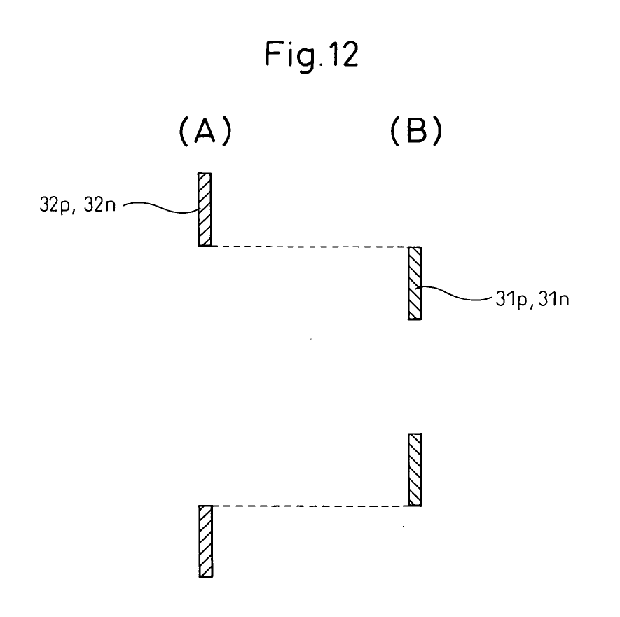

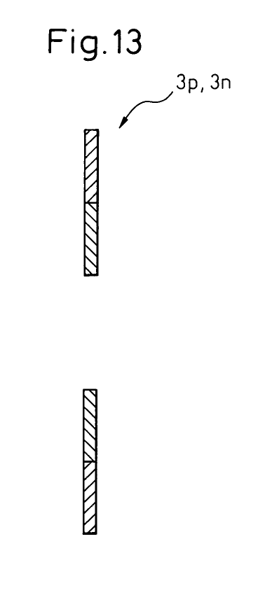

In this embodiment, as shown in FIG. 12, respective semiconductors 31p, 32p (31n, 32n) having substantially annular flat plate-like shapes were prepared in advance, and a semiconductor 3p (3n) shown in FIG. 13 was obtained by combining the respective semiconductors so prepared. Thereafter, respective heat insulating support members 41, 42 and the semiconductors 3p, 3n were stacked together to thereby obtain a thermoelectric module.

Here, as to the respective semiconductors 31p, 32p, 31n, 32n, desired shapes may be obtained directly by virtue of calcination or desired shapes can be realized by machining calcined products. In addition, as shown in FIG. 13, in combining the semiconductor 31p (31n) with the semiconductor 32p (32n), the two members may be brought into direct abutment with each other or may be brought into abutment with each other via a conductive paste material such as a sliver paste.

Thereafter, as shown in FIG. 6, the substantially annular flat plate-like semiconductors 3p and 3n are joined to sides of the primary heat insulating support member 41 having a high temperature side heat exchanging portion 210 which is fitted therein to thereby obtain a stacking component 20a.

Then, a predetermined number of stacking components 20a so obtained and the predetermined number of stacking components 20b (FIG. 7) constituted by secondary heat insulating support members 42 having low temperature side heat exchanging portions 220 which are fitted thereon are stacked alternately, whereby a thermoelectric module similar to that of the first embodiment is obtained.

Note that the other constructions, functions and advantages of the second embodiment remain similar to those of the first embodiment.

### Third Embodiment

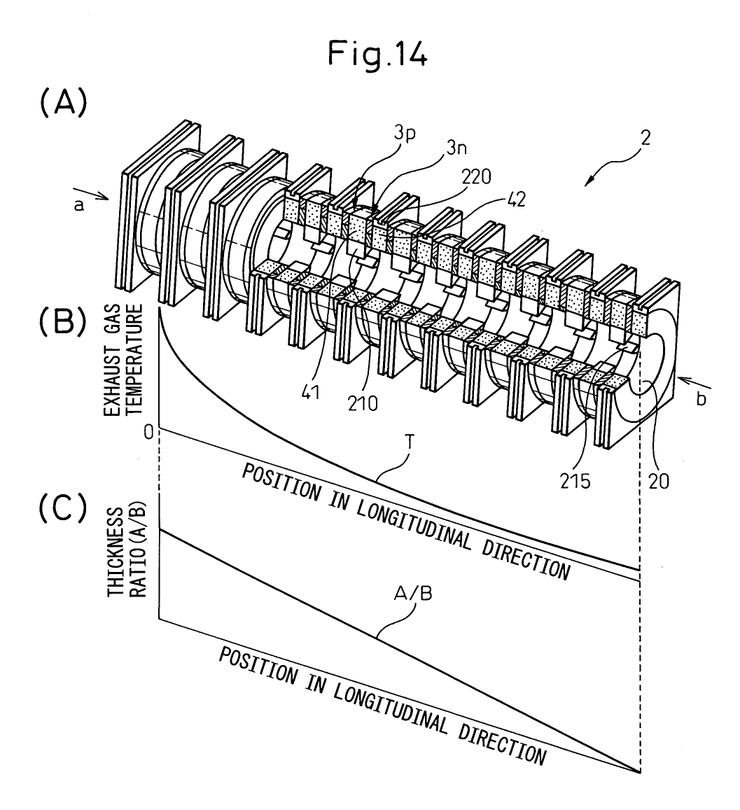

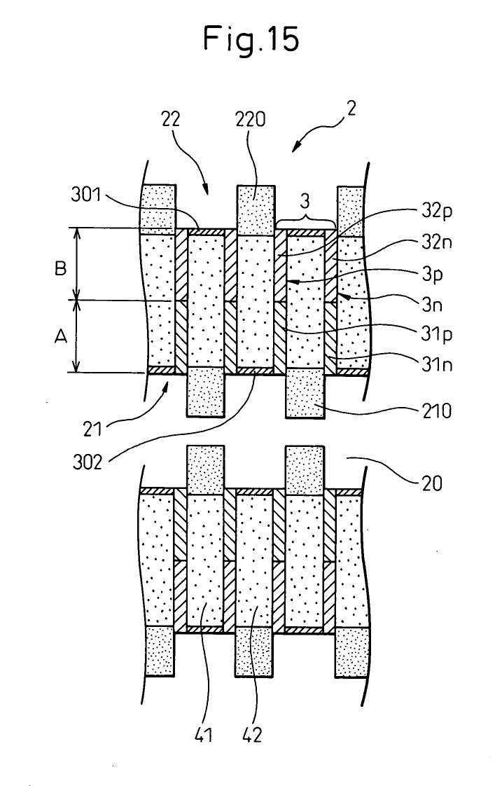

A third embodiment is such that the configuration of separated thermoelements is modified based on the exhaust heat recovery system according to the first embodiment. The contents of the third embodiment will be described using FIGS. 14 and 15.

In a thermoelectric module 2 according to this embodiment, as shown at a portion (A) in FIG. 14 and in FIG. 15, a ratio (A/B) of the radial thickness A (FIG. 15) of high temperature elements 31p, 31n which are separated thermoelements of a high temperature side end portion 21 and the radial thickness B (FIG. 15) of low temperature elements 32p, 32n which are separated thermoelements of a low temperature side end portion 22 is made to change according to location in a longitudinal direction of an exhaust pipe portion 20.

Namely, as shown at a portion (B) in FIG. 14, the temperature T of exhaust gases changes depending on positions along the longitudinal direction of the exhaust pipe portion 20 and is highest at a most upstream end (a) of the thermoelectric module 2. Then, the temperature T of exhaust gases decreases towards a downstream end of the thermoelectric module 2 and is lowest at a most downstream end (b) thereof. Then, in this embodiment, as shown at a portion (C) in FIG. 14, the ratio (A/B) of the radial thickness A of the high temperature elements and the radial thickness B of the low temperature elements is made to change according to positions along the longitudinal direction of the exhaust pipe portion 20.

In this embodiment, as shown at the portion (B) and at the portion (C) in FIG. 14, the thickness ratio (A/B) is made to increase towards the end (a) of the thermoelectric module 2 and, hence, as the temperature T of exhaust gases increases, so that the radial thickness of the high temperature elements 31p, 31n becomes thicker. On the other hand, the thickness ratio (A/B) is made to decrease towards the end (b) of the thermoelectric module 2 and hence as the temperature T of exhaust gases decreases, the radial thickness of the low temperature elements 31p, 31n becomes thicker. Note that, as shown at the portion (C) in FIG. 14, the thickness ratio (A/B) is made to become zero at the end (b) of the thermoelectric module 2, so that a thermoelement 3 constituted only by the low temperature elements 32p, 32n is provided at the same end of the thermoelectric module 2.

In this case, more efficient exhaust heat recovery can be implemented in accordance with temperatures of exhaust gases with which high temperature side heat exchanging portions are brought into contact.

Note that the other constructions, functions and advantages of the third embodiment remain similar to those of the first embodiment.

Furthermore, note that, in order to reduce the number of types of components required to constitute the thermoelectric module 2, it is effective to divide the thermoelectric module 2 into several longitudinal sections and to keep the thickness ratio (A/B) at the same value within each section.

While the invention has been described by reference to the specific embodiments chosen for purposes of illustration, it should be apparent that numerous modifications could be made thereto, by those skilled in the art, without departing from the basic concept and scope of the invention.

1. An exhaust gas recovery system comprising an exhaust path which allows the passage of exhaust gases of an internal combustion engine therethrough and a thermoelectric module disposed in the exhaust path, the thermoelectric module including;
an exhaust pipe portion which is a space for allowing the passage of the exhaust gases therethrough,
p-type semiconductors and n-type semiconductors which both constitute thermoelements for converting a difference in temperature between high temperature side end portions and low temperature side end portions into electricity,
low temperature side heat exchanging portions disposed at the low temperature side end portions, and
high temperature side heat exchanging portions disposed at the high temperature side end portions, wherein
in the thermoelectric module, the n-type semiconductors and the p-type semiconductors are stacked alternately along a longitudinal direction of the exhaust pipe portion, with heat insulating support members being interposed therebetween, and are electrically connected to each other at the high temperature side end portions and the low temperature side end portions via electrode members.

2. An exhaust heat recover system as set forth in claim 1 wherein, in the thermoelectric module, the thermoelement is made up of a combination of a plurality of separated thermoelements which have different peak temperatures where a maximum thermoelectric efficiency can be obtained, and wherein the respective semiconductors which make up the separated thermoelements having a higher peak temperature are disposed close to the exhaust pipe portion.

3. An exhaust heat recovery system as set forth in claim 1 wherein, in the thermoelectric module, two or more combinations of the n-type semiconductor and the p-type semiconductor are stacked together along the longitudinal direction of the exhaust pipe portion, and wherein the arrangement of the respective thermoelements is modified such that a ratio (A/B) of a thickness A in a radial direction of the respective semiconductors which make up a high temperature element which is the separated thermoelement having a highest peak temperature and a thickness B in a radial direction of the respective semiconductors which make up a low temperature element having a lowest peak temperature becomes larger towards an upstream side of the exhaust pipe portion.

4. An exhaust heat recovery system as set forth in claim 1, wherein the n-type semiconductor, the p-type semiconductor and the heat insulating support member are each formed into an annular shape having a through hole provided in an inner circumferential portion thereof, and wherein the exhaust pipe portion is formed on an inner circumferential side of the n-type semiconductor, the p-type semiconductor and the heat insulating support member which are stacked together in such a manner that the respective through holes communicate with one another.

5. An exhaust heat recovery system as set forth in claim 1, wherein the electrode member is a conductive layer which is disposed on part of an external surface of the heat insulating support member.

6. An exhaust heat recovery system as set forth in claim 1, wherein the electrode member is the high temperature side heat exchanging portion and the low temperature side heat exchanging portion.

7. An exhaust heat recovery system as set forth in claim 1, wherein the high temperature side heat exchanging portion protrudes into the interior of the exhaust pipe portion.
